(19) United States
(12) Patent Application Publication
(10) Pub. No.: US 2024/0344228 A1
(43) Pub. Date: Oct. 17, 2024

(54) FLIMS, METHODS OF PREPARING THE SAME, AND DISPLAY PANELS

(71) Applicant: Shenzhen China Star Optoelectronics Semiconductor Display Technology Co., Ltd., Shenzhen (CN)

(72) Inventors: Jinyang ZHAO, Shenzhen (CN); Hangchuan ZHANG, Shenzhen (CN)

(73) Assignee: Shenzhen China Star Optoelectronics Semiconductor Display Technology Co., Ltd., Shenzhen (CN)

(21) Appl. No.: 18/399,374

(22) Filed: Dec. 28, 2023

(30) Foreign Application Priority Data
Apr. 12, 2023 (CN) 202310418277.5

(51) Int. Cl. C25D 9/02; C25D 7/00

(52) U.S. Cl. CPC C25D 9/02; C25D 7/006; H10K 59/80

(57) ABSTRACT

Embodiments of the present disclosure provide a film, a method of preparing the same, and a display panel. The method of preparing the film includes: providing a solution, providing a first electrode and a second electrode, and providing a power source; two poles of the power source are electrically connected to the first electrode and the second electrode, respectively, so that the first electrode have a first electrical property, the second electrode has a second electrical property, first nanomaterials are deposited on a surface of the second electrode, the first monomer materials are cross-linked and polymerized on the surface of the second electrode, so as to form the film on the surface of the second electrode.

### CROSS-REFERENCE TO RELATED APPLICATION

This application claims the priority to and benefit of Chinese Patent Application No. 202310418277.5, filed on Apr. 12, 2023, the disclosure of which is incorporated herein by reference in its entirety.

### TECHNICAL FIELD

The present disclosure relates to the field of display, and in particular, to films, methods of preparing the same, and display panels.

### BACKGROUND

Nanomaterials, such as quantum dots (QDs), have the characteristics of small size, high efficiency of energy conversion, high brightness, narrow emission wavelengths, adjustable emission colors, and good stability, and therefore have significant application prospects in the field of illumination, display technology, solar cells, optical switches, sensing, and detection, and are also the most promising materials for display technology in recent years.

At present, the preparation of nanomaterials such as quantum dots mainly uses inkjet printing, photolithography process, and electrochemical deposition. The inkjet printing has high requirements for ink, and it is difficult to achieve mature and stable mass production and has poor repeatability, while the lithography process involves heating, ultraviolet curing, developer rinsing and other steps, which affects the stability of quantum dots. The electrochemical deposition only deposits quantum dot materials separately to prepare thin films, and the stability of such films is poor and easy to be removed in the process, resulting in the limited application of nanomaterials in the field of display technology.

Therefore, there is a need for a film, a method of preparing the same, and a display panel, to solve the above-mentioned technical problems.

### SUMMARY

Embodiments of the present disclosure provide a method of preparing a film, including:
providing a solution including first nanomaterials and first monomer materials, in which the first nanomaterials have a first electrical property;
providing a first electrode and a second electrode, in which both of the first electrode and the second electrode are at least partially located in the solution; and
providing a power source, in which two poles of the power source are electrically connected to the first electrode and the second electrode, respectively, so that the first electrode has the first electrical property, the second electrode has a second electrical property. The first nanomaterials are deposited on a surface of the second electrode, and the first monomer materials are cross-linked and polymerized on the surface of the second electrode, to form the film on the surface of the second electrode.

Embodiments of the present disclosure further provide a film including first nanomaterials and a first polymer, in which the first polymer is obtained by cross-linking and polymerization of at least first monomer materials.

Embodiments of the present disclosure further provide a display panel including the above-mentioned film.

### BRIEF DESCRIPTION OF THE DRAWINGS

In order to explain technical solutions in the embodiments of the present disclosure more clearly, the following will briefly introduce the drawings needed to be used in description of the embodiments. Apparently, the drawings in the following description are only some embodiments of the present disclosure. For those skilled in the art, other drawings can be obtained from these drawings without paying creative effort.

FIG. 1 is a schematic flowchart of a method of preparing a film according to one or more embodiments of the present disclosure.

FIG. 2 is a schematic structural diagram of the film in a first preparation method according to one or more embodiments of the present disclosure.

FIG. 3 is a schematic structural diagram of the film in a second preparation method according to one or more embodiments of the present disclosure.

### DETAILED DESCRIPTION

In combination with drawings in embodiments of the present disclosure, technical solutions in the embodiments of the present disclosure will be described clearly and completely. Apparently, the described embodiments are only part of the embodiments of the present disclosure, not all of them. Based on the embodiments of the present disclosure, all other embodiments obtained by those skilled in the art without creative effort belong to the scope of the present disclosure. In addition, it should be understood that specific embodiments described herein are only used to explain and interpret the present disclosure and are not used to limit the present disclosure. In the present disclosure, the directional terms used, such as “up” and “down”, generally refer to up and down directions of the device in actual use or working state, in particular drawing directions in the drawings; and terms “inside” and “outside” refer to outlines of the devices, unless otherwise described.

At present, the preparation of films containing nanomaterials such as quantum dots is limited by existing preparation processes, resulting in difficulties in achieving industrial application of the films containing such nanomaterials in the field of display technology and the like.

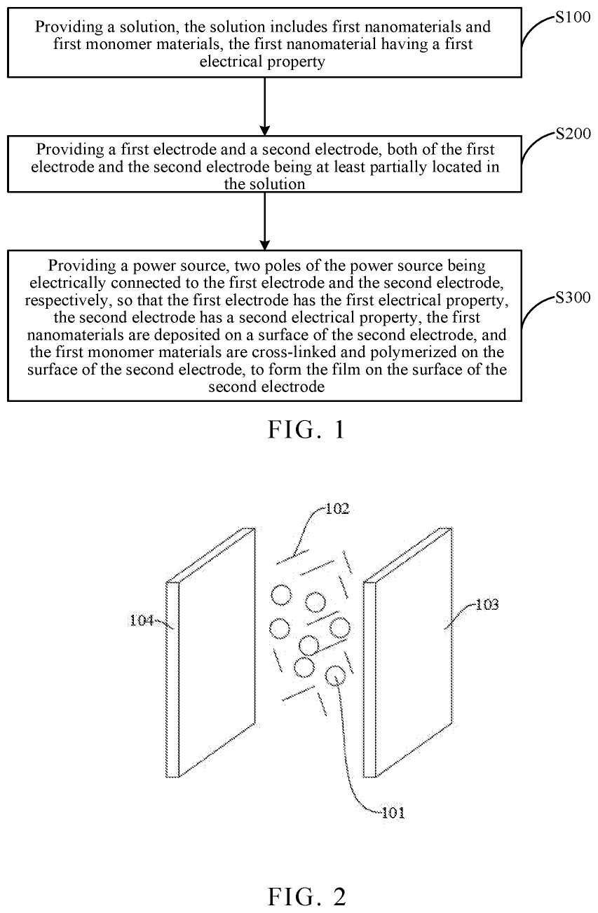

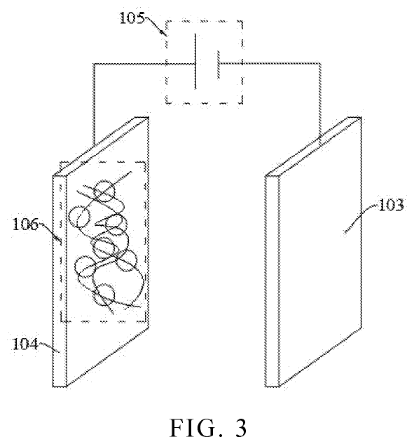

Referring to FIG. 1, FIG. 2, and FIG. 3, the embodiments of the present disclosure provide a method of preparing a film including:
step S100, a solution including first nanomaterials 101 and first monomer materials 102 is provided, and the first nanomaterials 101 have a first electrical property;
step S200, a first electrode 103 and a second electrode 104 are provided; the first electrode 103 is at least partially located in the solution, and the second electrode 104 is at least partially located in the solution; and
step S300, a power source 105 is provided; two poles of the power source 105 are electrically connected to the first electrode 103 and the second electrode 104, respectively, so that the first electrode 103 has the first electrical property, the second electrode 104 has a second electrical property, the first nanomaterials 101 are deposited on a surface of the second electrode 104, and the first monomer materials 102 are cross-linked and polymerized on the surface of the second electrode 104, to form the film 106 on the surface of the second electrode 104.

Due to the cross-linking polymerization of the first monomer materials 102, the film prepared by the method of preparing the film provided by the present disclosure is dense and stable, thus improving the stability of the film and facilitating the industrial application of the film.

Further, the first monomer materials 102 separate the first nanomaterials 101 because of the cross-linking polymerization of the first monomer materials 102, filling the gap between the first nanomaterials 101 to make the film dense, while reducing the self-absorption effect of the first nanomaterials 101 when they are quantum dots, which improves luminous efficiency of the film and further facilitates the industrial application of the film.

Meanwhile, the cross-linking polymerization of the first monomer materials 102 on the surface of the second electrode 104 enhances the firmness of the fixation between the film and the second electrode 104. When the film is used together with the second electrode 104 in display panels, the stability of the film can be further enhanced, which is further conducive to the industrial application of the film.

Technical solutions of the present disclosure are described with reference to specific embodiments.

Referring to FIG. 1 and FIG. 2, in some embodiments, at step S100, a solution including the first nanomaterials 101 and the first monomer materials 102 is provided, and the first nanomaterials 101 have the first electrical property. The step S100 may include:
step S110, the first nanomaterials 101 and the first monomer materials 102 are dispersed in a first solvent to obtain the solution.

There is no specific limitation on the order in which the first nanomaterials 101 and the first monomer materials 102 are dispersed in the first solvent. For example, the first nanomaterials 101 may be first dispersed in the first solvent, the first monomer materials 102 may be first dispersed in the first solvent, or the first nanomaterials 101 and the first monomer materials 102 are first mixed and then co-dispersed in the first solvent.

In some embodiments, the solution may also include second nanomaterials, which are different from the first nanomaterials 101 and have the same electrical property as the first nanomaterials 101.

When the solution includes the second nanomaterials, the step S100 may include:
step S120, the first nanomaterials 101, the second nanomaterials, and the first monomer materials 102 are dispersed in the first solvent to obtain the solution.

There is no specific limitation on the order in which the first nanomaterials 101, the second nanomaterials, and the first monomer materials 102 are dispersed in the first solvent.

When the solution includes the first nanomaterials 101 and the second nanomaterials, a mass ratio of the first nanomaterials 101 to the second nanomaterials may range from 1:10 to 10:1, for example, 1:8, 1:5, 1:3, 1:1, 2:1, 3:1, 5:1, 8:1, or the like. A sum of a mass percentage of the first nanomaterials 101 in the solution and a mass percentage of the second nanomaterials in the solution is less than or equal to 50%, for example, 5%, 10%, 15%, 20%, 25%, 30%, 35%, 40%, 45%, or the like. A sum of a concentration of the first nanomaterials 101 in the solution and a concentration of the second nanomaterials in the solution is less than or equal to 500 mg/mL, for example, 0.1 mg/mL, 0.5 mg/mL, 1 mg/mL, 50 mg/mL, 100 mg/mL, 150 mg/mL, 200 mg/mL, 250 mg/mL, 300 mg/mL, 350 mg/mL, 400 mg/mL, 450 mg/mL, or the like, to facilitate good dispersion of the first nanomaterials 101 and the second nanomaterials in the first solvent.

In some embodiments, the first nanomaterials 101 may be selected from quantum dots that emit red light, green light, or blue light.

Both of the first nanomaterials 101 and the second nanomaterials may be selected from one or more of nanoparticles such as inorganic nanoparticles, organic nanoparticles, noble metal nanoparticles, colloidal nanosheets, colloidal nanorods, and the like. In some embodiments, both of the first nanomaterials 101 and the second nanomaterials may be selected from at least one of nanomaterials such as quantum dots, titanium dioxide, zinc oxide, silicon dioxide, tin oxide, zirconium dioxide, barium sulfate, barium titanate, calcium carbonate, zinc selenide, zinc sulfide, silicon nitride, and the like. When both of the first nanomaterials 101 and the second nanomaterials are selected from quantum dots, the first nanomaterials 101 and the second nanomaterials are selected from different quantum dots that emit the same color of light. For example, when the first nanomaterials 101 are selected from quantum dots that emit red light, the second nanomaterials are also selected from quantum dots that emit red light. Preferably, when the first nanomaterials 101 are selected from quantum dots, the second nanomaterials are selected from at least one of nanomaterials such as titanium dioxide, zinc oxide, silicon dioxide, tin oxide, zirconium dioxide, barium sulfate, barium titanate, calcium carbonate, zinc selenide, zinc sulfide, silicon nitride, and the like, according to different preset functions. The second nanomaterials may be selected from at least one of nanomaterials such as titanium dioxide, zinc oxide, silicon dioxide, and the like, to improve light efficiency of the film 106. Silicon dioxide used as the nanomaterial is beneficial to spacing quantum dots, which can reduce self-absorption of the quantum dots, thus improving the light efficiency of the film 106. Titanium dioxide and silicon oxide used in the film 106 have the function of light-scattering while reducing self-absorption of the quantum dots by spacing the quantum dots, which is conducive to further improving the light efficiency of the film 106. A particle size of the first nanomaterials 101 ranges from 10 nanometers to 15 nanometers, and a particle size of the second nanomaterials ranges from 15 nanometers to 30 nanometers.

The quantum dots may include a light-emitting nucleus and an inorganic protective shell cladded outside the light-emitting nucleus. A material of the light-emitting nucleus includes at least one of ZnCdSe₂, InP, Cd₂SSe, CdSe, Cd₂SeTe, and InAs, and a material of the inorganic protective shell includes one of CdS, ZnSe, ZnCdS₂, ZnS, ZnO, or combinations thereof.

The quantum dots may also include composite quantum dots with high stability and perovskite quantum dots, and the composite quantum dots with high stability include quantum dots having a QD structure loaded with hydrogel or CdSe—SiO₂.

Surfaces of nanoparticles from which the first nanomaterials 101 and the second nanomaterials are selected are equipped with ligands. Specifically, the surfaces of the first nanomaterials 101 are equipped with a first ligand, and the surfaces of the second nanomaterials are equipped with a second ligand. The first ligand and the second ligand may include common organic ligands, for example, organic amine, organic acid, mercaptol alcohol, organic phosphorus, and the like. The first ligand and the second ligand may include groups that can ionize in the first solvent, which is beneficial to effectively increasing surface charges of the first nanomaterials 101 and/or surface charges of the second nanomaterials, and increasing conductivity of the solution. Moreover, the directional movement of the first nanomaterials 101 and/or the second nanomaterials can also generate current, providing ion channels for the occurrence of electrochemical polymerization reaction, which is beneficial to promoting the electrochemical polymerization of the first monomer materials 102. Further, the first ligand and the second ligand may include organic amine, organic acid, mercaptol alcohol, organic phosphorus, or other types of ionic groups. The other types of ionic groups may include anionic or cationic groups used in salt-based surfactants, such as dodecyl sulfonic acid, dodecanoic acid, or the like.

In some embodiments, the surfaces of the first nanomaterials 101 are equipped with the first ligand that has first electrochemical active groups, and the surfaces of the first monomer materials 102 are equipped with second electrochemical active groups. The first nanomaterials 101 and the first monomer materials 102 are cross-linked through the electrochemical polymerization reaction between the first electrochemical active groups and the second electrochemical active groups. At least a part of the first nanomaterials 101 are cross-linked through the electrochemical polymerization reaction of the first electrochemical active groups, and at least a part of the first monomer materials 102 are cross-linked through the electrochemical polymerization reaction with the second electrochemical active groups.

In some embodiments, when the solution further includes the second nanomaterials, the surfaces of the second nanomaterials may be equipped with the second ligand that has third electrochemical active groups, and the third electrochemical active groups may undergo electrochemical polymerization reaction with the first and/or second electrochemical active groups, so that the second nanomaterials are cross-linked with the first nanomaterials 101 and/or the first monomer materials 102. The third electrochemical active groups may undergo electrochemical polymerization reaction, so that the second nanomaterials are cross-linked with each other.

The first electrochemical active groups and/or the third electrochemical active groups may be selected from at least one of monomer groups such as aniline group, pyrrolyl, pyridinyl, anthraquinonyl, styryl, pyranyl, oxazinyl, thienyl, thianyl, triaminophenyl, pyrazolyl, phenazinyl, phenoxazinyl, and derived groups thereof.

In some embodiments, the first monomer materials 102 may be selected from at least one of monomers such as aniline, pyrrole, pyridine, anthraquinone, styrene, pyran, oxazine, thiophene, thiapyran, triphenylamine, pyrazoline, phenazine, phenoxazine, and derivatives thereof. A concentration of the first monomer materials 102 in the solution is greater than or equal to 0.1 mol/L and less than or equal to 2 mol/L, for example, the concentration of the first monomer materials 102 may be 0.15 mol/L, 0.2 mol/L, 0.5 mol/L, 0.8 mol/L, 1 mol/L, 1.2 mol/L, 1.5 mol/L, 1.8 mol/L, or the like, to obtain a suitable thickness of the film 106. A polymer formed by the polymerization of the first monomer materials 102 is a transparent polymer. Preferably, the polymer prepared by the polymerization of the first monomer materials 102 is colorless and transparent, which is beneficial to the application of the film 106. When the first nanomaterials 101 are quantum dots, light emitted by the first nanomaterials 101 can be prevented from being absorbed by the polymer prepared by the first monomer materials 102 in the film 106, thus improving light extraction efficiency of the film 106.

In some embodiments, the first solvent may be a non-polar solvent or a polar solvent. When the first solvent is selected from the non-polar solvent, the first solvent may include at least one of benzene, an alkane, carbon tetrachloride, and the like, and the alkanes may include cyclohexane, n-hexane, n-octane, and the like. When the first solvent is selected from the polar solvent, the first solvent may include at least one of ethanol, 2-acetoxy-1-methodopropane (PGMEA), ethyl acetate, N, N-dimethylformamide, and dimethyl sulfoxide.

In some embodiments, the solution further includes an electrolyte, and the step S100 may include:
step S130, the first nanomaterials 101, the first monomer materials 102, and the electrolyte are dispersed in the first solvent to obtain the solution; or,
step S140, the first nanomaterials 101, the second monomer materials, the first monomer materials 102, and the electrolyte are dispersed in the first solvent to obtain the solution.

The electrolyte may be selected from at least one of salt-based electrolytes such as tetrabutylammonium fluoride, tetramethylammonium hydroxide, tetrabutylammonium tetrafluoroborate, ammonium phosphate, lithium hexafluorophosphate, and the like.

A concentration of the electrolyte in the solution is greater than or equal to 0 mol/L and less than or equal to 0.1 mol/L. For example, the concentration of the electrolyte in the solution may be 0.01 mol/L, 0.02 mol/L, 0.05 mol/L, 0.06 mol/L, 0.08 mol/L, or the like. The concentration of the electrolyte in the solution may be 0 mol/L, that is, the electrolyte is not added in the solution. For example, when the first solvent is a polar solvent, and the ligands modifying the surfaces of the first nanomaterials 101 and/or the surfaces of the second nanomaterials have a group that can be ionized in the first solvent, the first nanomaterials 101 and/or the second nanomaterials can be used as the electrolyte, so that the addition of the electrolyte can be reduced or even be omitted, thus reducing the manufacturing cost of the film 106.

In some embodiments, when the solution is composed of the first solvent, the first nanomaterials 101, the second nanomaterials, the first monomer materials 102, and the electrolyte, the first solvent may be propylene glycol methyl ether acetate, the first nanomaterials 101 may be quantum dots modified by SH-PEG-COOH, and the second nanomaterials may be SiO₂ modified by silane PEG-COOH, in which SH indicates sulfydryl, PEG indicates polyethylene glycol, and the average molecular weight (Mn) of PEG may range from 400 to 1000, for example, 500, 600, 800, 1000, 2000, 5000, 8000, or the like. The particle size of the first nanomaterials 101 ranges from 10 nanometers to 15 nanometers, and the particle size of the second nanomaterials ranges from 15 nanometers to 30 nanometers. The first monomer materials 102 may be aniline, and the electrolyte may be tetrabutylammonium tetrafluoroborate.

Referring to FIG. 1 and FIG. 2, in some embodiments, at step S200, the first electrode 103 and the second electrode 104 are provided, the first electrode 103 is at least partially located in the solution, and the second electrode 104 is at least partially located in the solution.

In some embodiments, the first electrode 103 may be disposed opposite to the second electrode 104, and a material of the first electrode 103 and a material of the second electrode 104 may be the same or different. The material of the first electrode 103 and/or the material of the second electrode 104 may be selected from conductive materials such as indium tin oxide, graphene, and conductive metals such as copper, silver, molybdenum, aluminum, and the like.

In some embodiments, the first electrode 103 is formed on a first substrate, and the second electrode 104 is formed on a second substrate. The first electrode 103 is disposed on a side of the first substrate close to the second electrode 104, and the second electrode 104 is disposed on a side of the second substrate close to the first electrode 103. A material of the first substrate and a material of the second substrate may be the same or different. In some embodiments, the material of the first substrate and/or the material of the second substrate may be selected from an inorganic glass, an organic glass, a hard insulation film material, or a soft insulation film material.

In some embodiments, the first electrode 103 may be disposed on a first substrate on the entire surface. The second electrode 104 may be disposed on the second substrate on the entire surface, or the second electrode 104 may be disposed on the second substrate in a patterned form. The specific setting method of the second electrode 104 is determined by the preset pattern of the film 106, and there is no specific limitation.

Referring to FIG. 1 and FIG. 3, in some embodiments, at step S300, the power source 105 is provided, and two poles of the power source 105 are electrically connected to the first electrode 103 and the second electrode 104, respectively, so that the first electrode 103 has the first electrical property, the second electrode 104 has the second electrical property. The first nanomaterials 101 are deposited on the surface of the second electrode 104, and the first monomer materials 102 are cross-linked and polymerized on the surface of the second electrode 104, so as to form the film 106 on the surface of the second electrode 104.

In some embodiments, the first electrode 103 is connected to a positive pole of the power source 105, so that the first electrical property of the first electrode 103 is positive, and the second electrode 104 is connected to a negative pole of the power source 105, so that the second electrical property of the second electrode 104 is negative; or, the first electrode 103 is connected to the negative pole of the power source 105, so that the first electrical property of the first electrode 103 is negative, and the second electrode 104 is connected to the positive pole of the power source 105, so that the second electrical property of the second electrode 104 is positive.

The poles that the first electrode 103 and the second electrode 104 connected to the power source 105 are determined by the electrical property of the surfaces of the first nanomaterials 101 and/or the electrical property of the surfaces of the second nanomaterials in the solution and the electrical property of electrodes at which the first monomer materials 102 undergo electrochemical polymerization. For example, when the first nanomaterials 101 are quantum dots modified by SH-PEG-COOH, the second nanomaterials are SiO₂ modified by silane-PEG-COOH, the first monomer materials 102 are aniline, and the surfaces of the first nanomaterials 101 and the second nanomaterials have negative charges, the first monomer materials 102 undergo electrochemical polymerization at the positive pole of the power source 105. In this case, the second electrode 104 is connected to the positive pole of the power source 105, and the first electrode 103 is connected to the negative pole of the power source 105.

In some embodiments, the step S300 includes:
step S310, the first nanomaterials 101 are deposited on the surface of the second electrode 104 to form a first deposition layer, and
step S320, the first monomer materials 102 are cross-linked and polymerized on the surface of the second electrode 104 to form a polymer layer,
in which the polymer layer at least partially covers the first deposition layer.

In some embodiments, when the surfaces of the first nanomaterials 101 are equipped with the first ligand that has the first electrochemical active groups, and the surfaces of the first monomer materials 102 are equipped with the second electrochemical active groups, the step S320 includes:
step S321, the first monomer materials 102 are cross-linked with each other through the second electrochemical active groups, and the first monomer materials 102 are cross-linked with the first electrochemical active groups equipped on the surfaces of the first nanomaterials 101 through the second electrochemical active groups, so as to form the polymer layer on the surface of the second electrode 104.

When the solution further includes the second nanomaterials, the step S300 includes:
step S330, the first nanomaterials 101 and the second nanomaterials are co-deposited on the surface of the second electrode 104 to form a co-deposition layer, and
step S340, the first monomer materials 102 are cross-linked and polymerized on the surface of the second electrode 104 to form a polymer layer,
in which the polymer layer at least partially covers the co-deposition layer.

In some embodiments, the surfaces of the first nanomaterials 101 are equipped with the first ligand that has the first electrochemical active groups, the surfaces of the first monomer materials 102 are equipped with the second electrochemical active groups, and the surfaces of the second nanomaterials are equipped with the second ligand that has the third electrochemical active groups, the step S340 includes:
step S341, the first monomer materials 102 are cross-linked with each other through the second electrochemical active groups, the first monomer materials 102 are cross-linked with the first electrochemical active groups equipped on the surfaces of the first nanomaterials 101 through the second electrochemical active groups, and the first monomer materials 102 are cross-linked with the third electrochemical active groups equipped on the surfaces of the second nanomaterials through the second electrochemical active groups, so as to form the polymer layer on the surface of the second electrode 104.

The first nanomaterials 101 and/or the second nanomaterials are deposited on the surface of the second electrode 104 through the electrophoretic deposition method. Due to the faster electrophoresis rate than the electrochemical polymerization rate of the first monomer materials 102, the first nanomaterials 101 and/or the second nanomaterials are first acted and deposited on the surface of the second electrode 104. Meanwhile, the movement of the first nanomaterials 101 and/or the second nanomaterials in the solution generates a current, which enhances the conductivity of the solution and facilitates the electrochemical polymerization of the first monomer materials 102.

In some embodiments, the first electrode 103 is disposed opposite to the second electrode 104, and the film 106 is formed on a surface of the second electrode 104 close to the first electrode 103. The voltage loaded between the first electrode 103 and the second electrode 104 preferably ranges from 1 volt to 10 volts, for example, 1 volt, 2 volts, 3 volts, 4 volts, 5 volts, 6 volts, 7 volts, 8 volts, 9 volts, 10 volts, or the like, which is conducive to the polymerization of the first monomer materials 102. The spacing between the first electrode 103 and the second electrode 104 preferably ranges from 1 micron to 50 microns, for example, 1 micron, 5 microns, 10 microns, 15 microns, 20 microns, 25 microns, 30 microns, 35 microns, 40 microns, 45 microns, 50 microns, or the like, to generate the electric field having sufficient strength when the voltage loaded between the first electrode 103 and the second electrode 104 ranges from 1 volt and 10 volts, making the first nanomaterials 101 and/or the second nanomaterials undergo electrodeposition.

In some embodiments, the method of preparing the film further includes the step of removing the residual solution from the surface of the film 106, and the removing process may be selected from at least one of heating evaporation and vacuum treatment.

According to the method of preparing the film provided by the embodiments of the present disclosure, due to the cross-linking polymerization of the first monomer materials 102, the film formed by the method of preparing the film is dense and stable, thus improving the stability of the film and facilitating the industrial application of the film.

The present disclosure further provides a film prepared by the method of preparing the film as described above.

In some embodiments, the film includes the first nanomaterials 101 and a first polymer, and the first polymer is obtained by the polymerization of at least the first monomer materials 102; or, the film includes the first nanomaterials 101, the second nanomaterials, and the first polymer, and the first polymer is obtained by the polymerization of at least the first monomer materials 102. The first nanomaterials 101, the second nanomaterials, and the first monomer materials 102 are described in the method of preparing the film mentioned above, and will not be repeated here.

In some embodiments, the film can be used in color filters of display panels (such as quantum dot color filters), quantum dot light-emitting diodes, quantum dot organic light-emitting diodes, and the like.

When various films are needed to be used in the same display panel, for example, when the films are used as color filters, and the films that can emit various colors of light are needed, various films may be disposed in the same layer and formed on the same substrate (for example, various films are formed on the second substrate). At this time, various patterned electrodes are formed on the second substrate (such as the second electrode, the third electrode, and the like, depending on the number of types of films to be formed), and the pattern of the electrodes on each second substrate is consistent with the pattern of the corresponding formed film. The second substrate, electrodes formed on the second substrate, and various films can be used in the display panel as a whole to omit the peeling process in the preparation processes of the films, which is beneficial to improving efficiency of the processes and reducing cost of the processes.

The present disclosure further provides a display panel, which includes the above-mentioned film.

In some embodiments, the display panel may be a liquid crystal display panel, an organic light-emitting diode (OLED) display panel, or a quantum dot light-emitting diode (QLED) display panel.

The embodiments of the present disclosure provide a film, a method of preparing the same, and a display panel. The method of preparing the film includes: providing a solution, providing a first electrode and a second electrode, and providing a power source; two poles of the power source are electrically connected to the first electrode and the second electrode, respectively, so that the first electrode has a first electrical property, the second electrode has a second electrical property, the first nanomaterial is deposited on a surface of the second electrode, the first monomer materials are cross-linked and polymerized on a surface of the second electrode, so as to form the film on the surface of the second electrode. Due to the cross-linking polymerization of the first monomer materials, the film prepared by the method of preparing the film provided by the present disclosure is dense and stable, thus improving the stability of the film and facilitating the industrial application of the film.

The film, the method of preparing the same, and the display panel provided by the embodiments of the present disclosure are described in detail. In this context, specific embodiments are used to illustrate a principle and implementation modes of the present disclosure. The description of the above-mentioned embodiments is only used to help understand a core idea of the present disclosure. At the same time, for those skilled in the art, according to the core idea of the present disclosure, there might be changes in specific embodiments and the scope of the present disclosure, which falls within the scope of the protection of the present disclosure. In conclusion, contents of the specification should not be interpreted as a limitation of the present disclosure.

What is claimed is:

1. A method of preparing a film comprising:
providing a solution comprising first nanomaterials and first monomer materials, wherein the first nanomaterials have a first electrical property;
providing a first electrode and a second electrode, wherein both of the first electrode and the second electrode are at least partially located in the solution; and
providing a power source, wherein two poles of the power source are electrically connected to the first electrode and the second electrode, respectively, so that the first electrode has the first electrical property, the second electrode has a second electrical property, the first nanomaterials are deposited on a surface of the second electrode, and the first monomer materials are cross-linked and polymerized on a surface of the second electrode, to form the film on the surface of the second electrode.

2. The method of preparing the film of claim 1, wherein the step of forming the film on the surface of the second electrode comprises:
depositing the first nanomaterials on the surface of the second electrode to form a first deposition layer; and
forming a polymer layer by cross-linking polymerization of the first monomer materials on the surface of the second electrode;
wherein the polymer layer at least partially covers the first deposition layer.

3. The method of preparing the film of claim 2, wherein surfaces of the first nanomaterials are equipped with a first ligand having a first electrochemical active group, and surfaces of the first monomer materials are equipped with a second electrochemical active group; and
in the step of forming the polymer layer, the first monomer materials are cross-linked through the second electrochemical active group, and the first monomer materials are cross-linked with the first electrochemical active group of the first nanomaterials with the second electrochemical active group to form the polymer layer on the surface of the second electrode.

4. The method of preparing the film of claim 1, wherein the solution further comprises second nanomaterials, and the second nanomaterials are different from the first nanomaterials and have the first electrical property.

5. The method of preparing the film of claim 4, wherein the step of forming the film on the surface of the second electrode comprises:
co-depositing the first nanomaterials and the second nanomaterials on the surface of the second electrode to form a co-deposition layer; and
forming a polymer layer by cross-linking polymerization of the first monomer materials on the surface of the second electrode;
wherein the polymer layer at least partially covers the co-deposition layer.

6. The method of preparing the film of claim 4, wherein the first nanomaterials are selected from quantum dots, and the second nanomaterials are selected from at least one of titanium dioxide, zinc oxide, silicon dioxide, tin oxide, zirconium dioxide, barium sulfate, barium titanate, calcium carbonate, zinc selenide, zinc sulfide, and silicon nitride.

7. The method of preparing the film of claim 6, wherein a particle size of the first nanomaterials ranges from 10 nanometers to 15 nanometers, and a particle size of the second nanomaterials ranges from 15 nanometers to 30 nanometers.

8. The method of preparing the film of claim 1, wherein the film formed by polymerization of the first monomer materials is a transparent film.

9. The method of preparing the film of claim 1, wherein the first monomer materials are selected from at least one of aniline, pyrrole, pyridine, anthraquinone, styrene, pyran, oxazine, thiophene, thiapyran, triphenylamine, pyrazoline, phenazine, phenoxazine, and derivatives thereof.

10. The method of preparing the film of claim 1, wherein a concentration of the first monomer materials in the solution is greater than or equal to 0.1 mol/L and less than or equal to 2 mol/L.

11. The method of preparing the film of claim 1, wherein the solution further comprises second nanomaterials, and the second nanomaterials are different from the first nanomaterials and have the first electrical property; and
wherein a mass ratio of the first nanomaterials to the second nanomaterials ranges from 1:10 to 10:1.

12. The method of preparing the film of claim 1, wherein the solution further comprises second nanomaterials, and the second nanomaterials are different from the first nanomaterials and have the first electrical property; and
wherein a sum of a mass percentage of the first nanomaterials in the solution and a mass percentage of the second nanomaterials in the solution is less than or equal to 50%.

13. The method of preparing the film of claim 1, wherein the solution further comprises second nanomaterials, and the second nanomaterials are different from the first nanomaterials and have the first electrical property; and
wherein a sum of a concentration of the first nanomaterials in the solution and a concentration of the second nanomaterials in the solution is less than or equal to 500 mg/mL.

14. The method of preparing the film of claim 1, wherein the step of providing the solution comprises dispersing the first nanomaterials and the first monomer materials in a first solvent to obtain the solution; and
wherein the first solvent is selected from one or more of benzene, an alkane, carbon tetrachloride, ethanol, 2-acetoxy-1-methodopropane, ethyl acetate, N, N-dimethylformamide, and dimethyl sulfoxide.

15. The method of preparing the film of claim 1, wherein the solution further comprises an electrolyte, and the step of providing the solution comprises dispersing the first nanomaterials, the first monomer materials, and the electrolyte in a first solvent to obtain the solution;
wherein the first solvent is selected from one or more of benzene, an alkane, carbon tetrachloride, ethanol, 2-acetoxy-1-methodopropane, ethyl acetate, N,N-dimethylformamide, and dimethyl sulfoxide; and
the electrolyte is selected from one or more of tetrabutylammonium fluoride, tetramethylammonium hydroxide, tetrabutylammonium tetrafluoroborate, ammonium phosphate, and lithium hexafluorophosphate.

16. The method of preparing the film of claim 15, wherein a concentration of the electrolyte in the solution is less than or equal to 0.1 mol/L.

17. The method of preparing the film of claim 1, wherein a material of the first electrode and/or a material of the second electrode is selected from one or more of indium tin oxide, graphene, and conductive metals.

18. The method of preparing the film of claim 1, wherein the first electrical property is positive, and the second electrical property is negative; or
the first electrical property is negative, and the second electrical property is positive.

19. A film comprising first nanomaterials and a first polymer, wherein the first polymer is obtained by cross-linking and polymerization of at least first monomer materials.

20. A display panel comprising a film, wherein the film comprises first nanomaterials and a first polymer; and
wherein the first polymer is obtained by cross-linking and polymerization of at least first monomer materials.
